(19) United States
(12) Patent Application Publication
(10) Pub. No.: US 2026/0083007 A1
(43) Pub. Date: Mar. 19, 2026

(54) SEMICONDUCTOR PACKAGE

(71) Applicant: Samsung Electronics Co., Ltd., Suwon-si (KR)

(72) Inventors: Wonil SEO, Suwon-si (KR); Yonghyun KIM, Suwon-si (KR); Taejun JEON, Suwon-si (KR)

(21) Appl. No.: 19/198,733

(22) Filed: May 5, 2025

(30) Foreign Application Priority Data
Sep. 19, 2024 (KR) 10-2024-0126637

(51) Int. Cl. H01L 25/18; H01L 23/00; H01L 23/498; H01L 23/538; H01L 25/065; H10B 80/00; H10D 80/30

(52) U.S. Cl. CPC H10W 90/00; H10B 80/00; H10D 80/30; H10W 70/60; H10W 70/611; H10W 70/65; H10W 90/701; H10W 72/07351; H10W 72/07354; H10W 72/347; H10W 72/367; H10W 72/823; H10W 72/834; H10W 90/24; H10W 90/724; H10W 90/732; H10W 90/734

(57) ABSTRACT

A semiconductor package may include a package substrate including first and second surfaces, which are opposite to each other, a first semiconductor chip on the first surface, a first mold layer on the first surface of the package substrate and top and side surfaces of the first semiconductor chip, a second semiconductor chip and a third semiconductor chip stacked on the second surface, a second mold layer on the second surface of the package substrate, bottom and side surfaces of the second semiconductor chip, and bottom and side surfaces of the third semiconductor chip, a vertical conductive pillar provided to penetrate the second mold layer in a vertical direction and horizontally spaced apart from the second and third semiconductor chips, and connection terminals between a bottom surface of the first semiconductor chip and the first surface. The vertical conductive pillar may be placed on the second surface.

### CROSS-REFERENCE TO RELATED APPLICATIONS

This U.S. non-provisional patent application claims priority under 35 U.S.C. § 119 to Korean Patent Application No. 10-2024-0126637, filed on Sep. 19, 2024, in the Korean Intellectual Property Office, the entire contents of which are hereby incorporated by reference.

### BACKGROUND OF THE INVENTION

The present disclosure relates to a semiconductor package.

A semiconductor package is configured to facilitate the use of an integrated circuit chip as a component in an electronic product. In general, the semiconductor package includes a printed circuit board (PCB) and a semiconductor chip, which is mounted on the PCB and is electrically connected to the PCB using bonding wires or bumps. With development of the semiconductor industry, many studies are being conducted to improve reliability of the semiconductor package.

### SUMMARY

An embodiment of the inventive concept provides a semiconductor package with a reduced thickness and a reduced plan view area.

An embodiment of the inventive concept provides a semiconductor package with improved reliability.

According to an embodiment of the inventive concept, a semiconductor package may include a package substrate including a first surface and a second surface, which are opposite to each other, a first semiconductor chip on the first surface, a first mold layer on the first surface of the package substrate and a top surface and a side surface of the first semiconductor chip, a second semiconductor chip and a third semiconductor chip stacked on the second surface, a second mold layer on the second surface of the package substrate, bottom and side surfaces of the second semiconductor chip, and bottom and side surfaces of the third semiconductor chip, a vertical conductive pillar, which is provided to penetrate the second mold layer in a vertical direction and is horizontally spaced apart from the second and third semiconductor chips, and connection terminals between a bottom surface of the first semiconductor chip and the first surface. The vertical conductive pillar may be placed on the second surface.

According to an embodiment of the inventive concept, a semiconductor package may include a package substrate including a first surface and a second surface, which are opposite to each other, the package substrate including a first substrate pad on the first surface and a second substrate pad on the second surface, a first semiconductor chip on the first surface, the first semiconductor chip including a first chip pad, a connection terminal between the first substrate pad and the first chip pad, a second semiconductor chip on the second surface, the second semiconductor chip including a second chip pad on a bottom surface thereof, a third semiconductor chip spaced apart from the package substrate with the second semiconductor chip interposed therebetween, the third semiconductor chip including a third chip pad on a bottom surface thereof, and a conductive pattern electrically connecting the second substrate pad, the second chip pad, and the third chip pad to each other. The conductive pattern may be in contact with the bottom surface of the second semiconductor chip and the bottom surface of the third semiconductor chip.

According to an embodiment of the inventive concept, a semiconductor package may include a package substrate including a first surface and a second surface, which are opposite to each other, the package substrate including a first substrate pad on the first surface and a second substrate pad and a third substrate pad on the second surface, a first semiconductor chip on the first surface, the first semiconductor chip including a first chip pad, a connection terminal between the first substrate pad and the first chip pad, a first mold layer on the first surface of the package substrate and top and side surfaces of the first semiconductor chip, a second semiconductor chip on the second surface of the package substrate, the second semiconductor chip including a second chip pad, a third semiconductor chip spaced apart from the package substrate with the second semiconductor chip interposed therebetween, the third semiconductor chip including a third chip pad, a first adhesive layer between the second surface and the second semiconductor chip, a second adhesive layer between the second semiconductor chip and the third semiconductor chip, a second mold layer on the second surface, a bottom surface of the second semiconductor chip, and bottom and side surfaces of the third semiconductor chip, a conductive pattern electrically connecting the second chip pad, the third chip pad, and the second substrate pad to each other, a vertical conductive pillar provided on the third substrate pad to penetrate the second mold layer in a vertical direction, and an outer connection terminal on the vertical conductive pillar. The conductive pattern may have a line shape extending in a direction parallel to the first surface, on the bottom surface of the second semiconductor chip.

### BRIEF DESCRIPTION OF THE DRAWINGS

FIG. 1A is a sectional view illustrating a semiconductor package according to an embodiment of the inventive concept.

FIG. 1B is a plan view illustrating a bottom surface of a package substrate.

FIG. 2A is an enlarged view illustrating a portion ‘EV1’ of FIG. 1A according to an embodiment.

FIG. 2B is an enlarged view illustrating the portion ‘EV1’ of FIG. 1A according to another embodiment.

FIG. 2C is an enlarged view illustrating the portion ‘EV1’ of FIG. 1A according to another embodiment.

FIG. 3A is an enlarged view illustrating a portion ‘EV2’ of FIG. 1A according to an embodiment.

FIG. 3B is an enlarged view illustrating the portion ‘EV2’ of FIG. 1A according to another embodiment.

FIG. 4A is a sectional view illustrating a semiconductor package according to an embodiment of the inventive concept.

FIG. 4B is a sectional view illustrating a semiconductor package according to an embodiment of the inventive concept.

FIGS. 5A to 5F are sectional views illustrating a process of fabricating a semiconductor package according to an embodiment of the inventive concept.

FIG. 6 is a sectional view illustrating a process of fabricating a semiconductor package according to an embodiment of the inventive concept.

### DETAILED DESCRIPTION

Example embodiments of the inventive concepts will now be described more fully with reference to the accompanying drawings, in which example embodiments are shown. Like reference numerals in the drawings denote like elements, and thus their duplicate descriptions will be omitted.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary.

Spatially relative terms, such as “beneath,” “below,” “lower,” “above,” “upper,” “top,” “bottom,” “front,” “rear,” “horizontal,” “vertical,” and the like, may be used herein for ease of description to describe positional relationships, such as illustrated in the figures, for example. It will be understood that the spatially relative terms encompass different orientations of the device in addition to the orientation depicted in the figures.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be transferred from one component to the other (although such electrical signal may be attenuated in strength as it is transferred and may be selectively transferred).

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

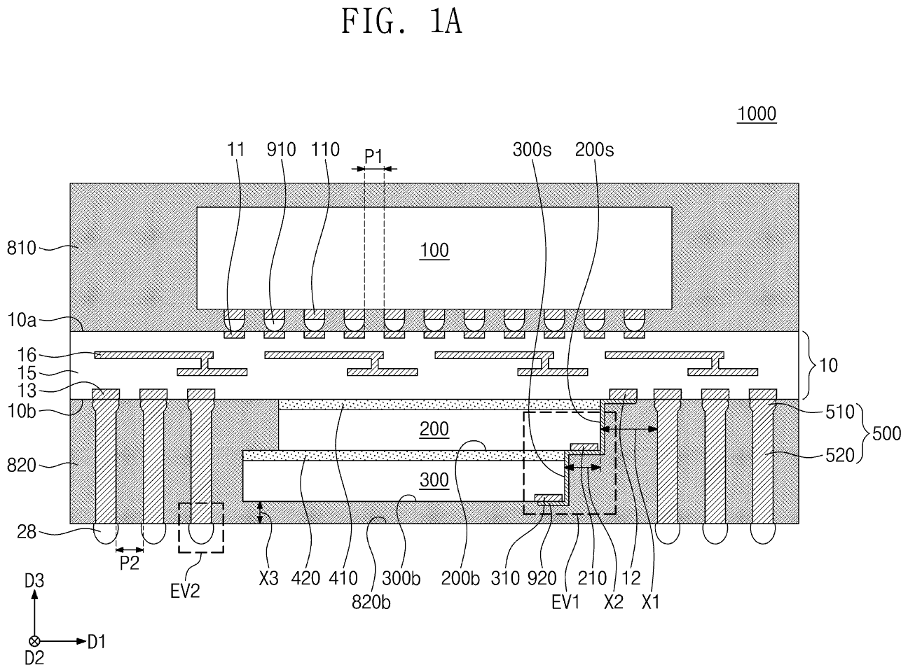

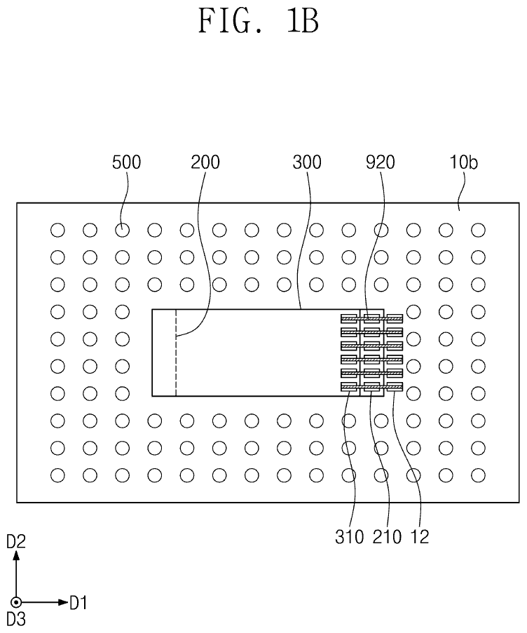

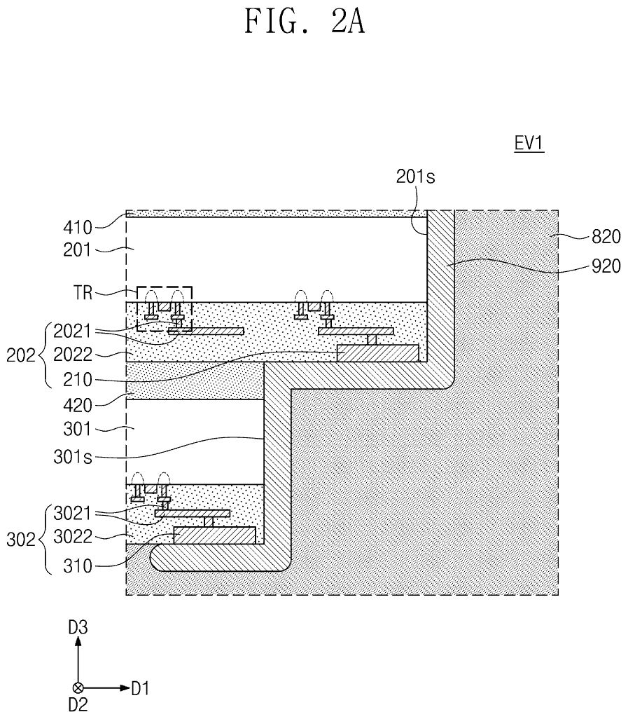

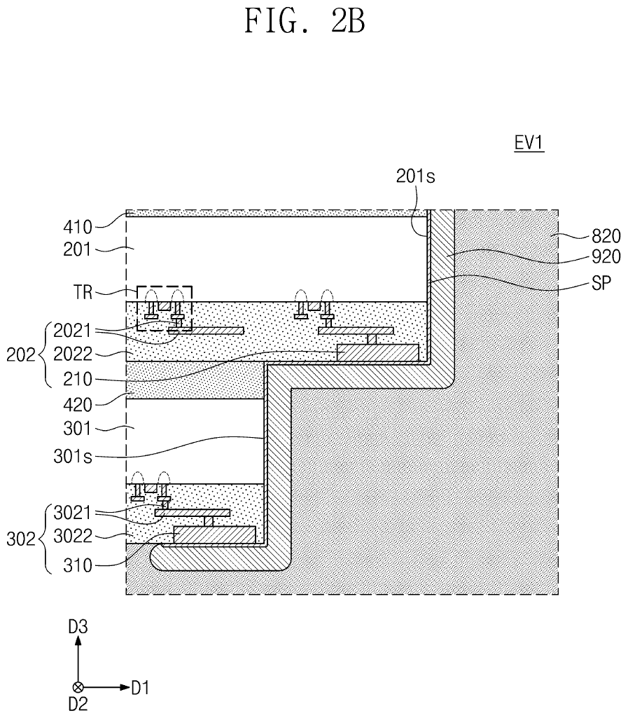

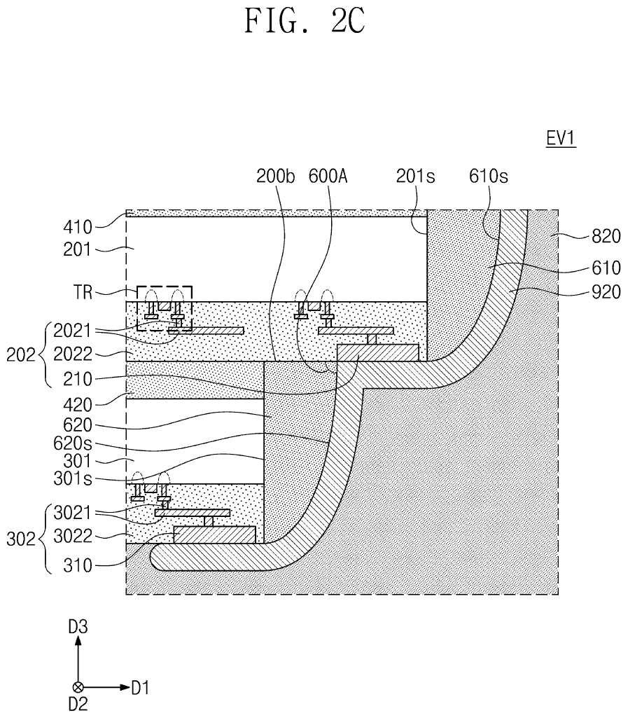

FIG. 1A is a sectional view illustrating a semiconductor package according to an embodiment of the inventive concept. FIG. 1B is a plan view illustrating a bottom surface of a package substrate. FIG. 2A is an enlarged view illustrating a portion ‘EV1’ of FIG. 1A according to an embodiment.

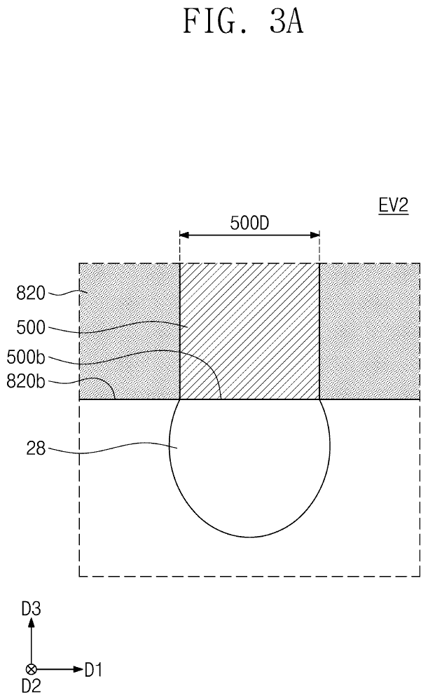

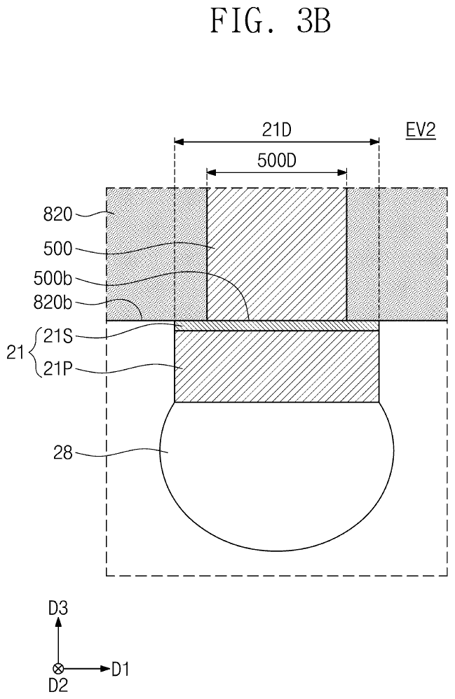

FIG. 2B is an enlarged view illustrating the portion ‘EV1’ of FIG. 1A according to another embodiment. FIG. 2C is an enlarged view illustrating the portion ‘EV1’ of FIG. 1A according to another embodiment. FIG. 3A is an enlarged view illustrating a portion ‘EV2’ of FIG. 1A according to an embodiment. FIG. 3B is an enlarged view illustrating the portion ‘EV2’ of FIG. 1A according to another embodiment.

Referring to FIGS. 1A and 1B, a semiconductor package 1000 may include a package substrate 10, a first semiconductor chip 100, a connection terminal 910, a first mold layer 810, a second semiconductor chip 200, a third semiconductor chip 300, a conductive pattern 920, a vertical conductive pillar 500, and a second mold layer 820.

The package substrate 10 may be, for example, a printed circuit board (PCB). The package substrate 10 may include a first surface 10a and a second surface 10b, which are opposite to each other. The first surface 10a and the second surface 10b may correspond to or may be top and bottom surfaces of the package substrate 10, respectively.

In the present specification, a first direction D1 may be parallel to the first surface 10a. A second direction D2 may be parallel to the first surface 10a, but not to the first direction D1. For example, the second direction D2 may be perpendicular to the first direction D1. A third direction D3 may be perpendicular to the first surface 10a. For example, the first and second directions D1 and D2 may be horizontal directions, and the third direction D3 may be a vertical direction.

The package substrate 10 may include an insulating layer 15, an interconnection structure 16, a first substrate pad 11, a second substrate pad 12, and a third substrate pad 13. In an embodiment, the insulating layer 15 may include glass fibers and an epoxy resin. The interconnection structure 16 may be disposed in the insulating layer 15. The interconnection structure 16 may include a plurality of interconnection lines and vias electrically connecting the interconnection lines to each other. The first substrate pad 11 may be disposed on the first surface 10a. In an embodiment, a plurality of first substrate pads 11 may be provided on the first surface 10a and may be arranged in the first and second directions D1 and D2 on the first surface 10a. The second and third substrate pads 12 and 13 may be disposed on the second surface 10b. In an embodiment, a plurality of second substrate pads 12 may be provided on the second surface 10b and may be arranged in the second direction D2 on the second surface 10b, as shown in FIG. 1B. In an embodiment, a plurality of third substrate pads 13 may be provided on the second surface 10b and may be arranged in the first and second directions D1 and D2 on the second surface 10b. A top surface of the first substrate pad 11, a bottom surface of the second substrate pad 12, and a bottom surface of the third substrate pad 13 may be exposed from the insulating layer 15. The interconnection structure 16 may electrically connect the first substrate pad 11, the second substrate pad 12, and the third substrate pad 13 to each other.

The first semiconductor chip 100 may be disposed on the first surface 10a of the package substrate 10. The first semiconductor chip 100 may be a logic chip. The first semiconductor chip 100 may include one of an application processor (AP), a graphics processing unit (GPU), a central processing unit (CPU), and an application-specific integrated circuit (ASIC). For example, the first semiconductor chip 100 may be an application processor (AP).

The first semiconductor chip 100 may include a plurality of first chip pads 110. In an embodiment, each of the first chip pads 110 may be provided to have a pillar shape or a cylindrical shape. However, the shape of the first chip pads 110 may be variously changed, and the first chap pads 110 may have various shapes. The first chip pads 110 and the first substrate pads 11 may be overlapped with each other in the third direction D3. The connection terminals 910 may be respectively disposed between the first chip pads 110 and the first substrate pads 11. Each of the connection terminals 910 may be, for example, a bump containing a soldering material. The soldering material may include tin (Sn), and in an embodiment, it may further include silver (Ag) or the like.

The first mold layer 810 may be disposed on the first surface 10a of the package substrate 10. The first mold layer 810 may cover top and side surfaces of the first semiconductor chip 100. The first mold layer 810 may extend to a region between the first semiconductor chip 100 and the first surface 10a of the package substrate 10 to fill a region between the connection terminals 910, e.g., in the first direction D1 and the second direction D2. The first mold layer 810 may include an epoxy molding compound (EMC).

The second and third semiconductor chips 200 and 300 may be disposed on the second surface 10b of the package substrate 10. The first semiconductor chip 100, the second semiconductor chip 200, and the third semiconductor chip 300 may share one package substrate 10. The first semiconductor chip 100 and the second and third semiconductor chips 200 and 300 may be respectively disposed on opposite surfaces of the package substrate 10 to form a single package structure. The second and third semiconductor chips 200 and 300 may be spaced apart from the first semiconductor chip 100 in the third direction D3, with the package substrate 10 interposed therebetween. The second and third semiconductor chips 200 and 300 may be semiconductor chips of a kind different from the first semiconductor chip 100. For example, the second and third semiconductor chips 200 and 300 may be memory chips. The second and third semiconductor chips 200 and 300 may be semiconductor chips of the same kind. For example, the second and third semiconductor chips 200 and 300 may be the dynamic random access memory (DRAM) chips. Alternatively, the second and third semiconductor chips 200 and 300 may be static random access memory (SRAM) chips or NAND FLASH chips. The second and third semiconductor chips 200 and 300 may be stacked on the second surface 10b to be offset from each other in the first direction D1, as shown in FIG. 1B. The third semiconductor chip 300 may be spaced apart from the second surface 10b, with the second semiconductor chip 200 interposed therebetween. Side surfaces of the third semiconductor chip 300 may not be aligned to side surfaces of the second semiconductor chip 200, e.g., in the vertical direction. For example, the side surfaces of the third semiconductor chip 300 may not vertically overlap the side surfaces of the second semiconductor chip 200 as shown in FIG. 1A. For example, two side surfaces of the third semiconductor chip 300 may not vertically overlap side surfaces of the second semiconductor chip 200, and two other side surfaces of the third semiconductor chip 300 may vertically overlap or be vertically aligned with side surfaces of the second semiconductor chip 200 as shown in FIG. 1B.

A first adhesive layer 410 may be interposed between the second semiconductor chip 200 and the package substrate 10. A second adhesive layer 420 may be interposed between the third semiconductor chip 300 and the second semiconductor chip 200. The first and second adhesive layers 410 and 420 may include a polymer material having an adhesive property. In an embodiment, each of the first and second adhesive layers 410 and 420 may be a die attach film (DAF).

The second semiconductor chip 200 may include a second chip pad 210. In an embodiment, a plurality of second chip pads 210 may be provided in the second semiconductor chip 200 and may be arranged in the second direction D2, as shown in FIG. 1B. The second chip pads 210 may be exposed from the third semiconductor chip 300 and the second adhesive layer 420. For example, the second chip pads 210 may not vertically overlap the third semiconductor chip 300 and the second adhesive layer 420 so that the third semiconductor chip 300 and the second adhesive layer 420 do not cover the second chip pads 210. The third semiconductor chip 300 may include a third chip pad 310. In an embodiment, a plurality of third chip pads 310 may be provided in the third semiconductor chip 300, and may be arranged in the second direction D2, as shown in FIG. 1B.

The conductive pattern 920 may be disposed on the second substrate pad 12, the second chip pad 210, and the third chip pad 310. The conductive pattern 920 will be described in more detail below.

Vertical conductive pillars 500 may be disposed on the second surface 10b of the package substrate 10. The vertical conductive pillars 500 may be spaced apart from the second and third semiconductor chips 200 and 300 in the first and/or second directions D1 and/or D2. The vertical conductive pillars 500 may enclose/surround the second and third semiconductor chips 200 and 300. The vertical conductive pillars 500 may be arranged in the first and second directions D1 and D2. The vertical conductive pillars 500 may be electrically connected to the third substrate pads 13, respectively. The vertical conductive pillars 500 may be in contact with the third substrate pads 13, respectively. Each of the vertical conductive pillars 500 may include a first portion 510 and a second portion 520. The first and second portions 510 and 520 may be connected to form a single object. For example, the first and second portions 510 and 520 may be integrally formed as one body without a boundary between them. The first portion 510 may have a larger width than the second portion 520, when measured in the first and second directions D1 and D2. The first portion 510 may be a portion of the vertical conductive pillar 500 that is in contact with the third substrate pad 13. For example, the first portion 510 may have a hemispherical shape. Alternatively, the first portion 510 may have a decreasing width as a distance from the third substrate pad 13 increases in a direction toward the second portion 520. The first portion 510 may have a curved side surface. The second portion 520 may have a line shape or a cylindrical shape extending (e.g., lengthwise) in the third direction D3. A length of the second portion 520 in the third direction D3 may be larger than a length of the first portion 510 in the third direction D3. Each of the vertical conductive pillars 500 may be a metal wire or a metal pin. Outer connection terminals 28 may be disposed on the bottom surfaces of the vertical conductive pillars 500, respectively. Each of the outer connection terminals 28 may include a solder. When viewed in a plan view, the outer connection terminals 28 may be spaced apart from the second and third semiconductor chips 200 and 300 and may be provided to enclose/surround the second and third semiconductor chips 200 and 300. This is because an additional redistribution layer or an additional substrate is not interposed between the vertical conductive pillars 500 and the outer connection terminals 28 and each of the outer connection terminals 28 overlaps a corresponding one of the vertical conductive pillars 500 in the third direction D3. A height of each of the vertical conductive pillars 500 may be larger than a sum of thicknesses of the second and third semiconductor chips 200 and 300, e.g., in the vertical direction.

The second mold layer 820 may be disposed on the second surface 10b of the package substrate 10. The second mold layer 820 may cover/contact side and bottom surfaces of the second semiconductor chip 200 and side and bottom surfaces of the third semiconductor chip 300. The second mold layer 820 may include, for example, an epoxy molding compound (EMC). The vertical conductive pillars 500 may cross or penetrate the second mold layer 820 in the third direction D3.

Referring to FIGS. 1A, 1B, and 2A, the conductive pattern 920 may be in contact with the second substrate pad 12, the second chip pad 210, and the third chip pad 310. The conductive pattern 920 may cover a bottom surface 300b and a side surface 300s of the third semiconductor chip 300, a bottom surface 200b and a side surface 200s of the second semiconductor chip 200, the second surface 10b of the package substrate 10, and side surfaces of the first and second adhesive layers 410 and 420. The conductive pattern 920 may be in contact with the bottom surface 300b of the third semiconductor chip 300, the bottom surface 200b of the second semiconductor chip 200, and the second surface 10b of the package substrate 10. In an embodiment, the conductive pattern 920 may be in contact with the side surface 300s of the third semiconductor chip 300 and the side surface 200s of the second semiconductor chip 200. The conductive pattern 920 may be a stepwise pattern that continuously extends from the second substrate pad 12 to the third chip pad 310. The conductive pattern 920 may have a line shape extending in the first direction D1, when viewed in a plan view as shown in FIG. 1B. The conductive pattern 920 may be formed of or include at least one of metallic materials (e.g., gold, silver, copper, and aluminum). As shown in FIG. 2A, the second semiconductor chip 200 may include a first semiconductor substrate 201 and a first interconnection layer 202. An integrated circuit (e.g., a transistor TR) may be disposed on an active region of the first semiconductor substrate 201. The first interconnection layer 202 may include a first insulating layer 2022, a first interconnection structure 2021, and the second chip pad 210. The first insulating layer 2022 may be formed of or include at least one of inorganic insulating materials (e.g., silicon oxide, silicon nitride, and silicon oxynitride). The first interconnection structure 2021 may include vias and interconnection lines. The first interconnection structure 2021 may electrically connect the integrated circuit (e.g., the transistor) to the second chip pad 210. The third semiconductor chip 300 may include a second semiconductor substrate 301 and a second interconnection layer 302. An integrated circuit (e.g., the transistor TR) may be disposed on the active region of the second semiconductor substrate 301. The second interconnection layer 302 may include a second insulating layer 3022, a second interconnection structure 3021, and the third chip pad 310. The second insulating layer 3022 may include an inorganic insulating material (e.g., silicon oxide, silicon nitride, or silicon oxynitride). The second interconnection structure 3021 may include a plurality of vias and a plurality of interconnection lines and may be provided to electrically connect the integrated circuit (e.g., transistor) to the third chip pad 310. The conductive pattern 920 may be in contact with a side surface 201s of the first semiconductor substrate 201 and a side surface 301s of the second semiconductor substrate 301. The conductive pattern 920 may be in contact with side and bottom surfaces of the first interconnection layer 202, side and bottom surfaces of the second interconnection layer 302, side surfaces of the first and second adhesive layers 410 and 420, and the second surface 10b of the package substrate 10. On the second surface 10b of the package substrate 10, the bottom surface 200b of the second semiconductor chip 200, and the bottom surface 300b of the third semiconductor chip 300, the conductive pattern 920 may have a line or line-like shape extending in the first direction D1. In the present specification, the expression ‘a pattern has a line shape’ may mean that the surface of the pattern is linear or partially curved, but does not form a loop shape like bonding wires. Thus, the second mold layer 820 may not be interposed between the conductive pattern 920 and the second surface 10b of the package substrate 10, the bottom surface 200b of the second semiconductor chip 200, and the bottom surface 300b of the third semiconductor chip 300.

Referring to FIGS. 1A and 2B, the conductive pattern 920 may further include a seed pattern SP. The seed pattern SP may include at least one of copper, titanium, chromium, or nickel. The seed pattern SP may be in contact with the side surface 201s of the first semiconductor substrate 201 and the side surface 301s of the second semiconductor substrate 301. The seed pattern SP may be in contact with the side and bottom surfaces of the first interconnection layer 202, the side and bottom surfaces of the second interconnection layer 302, the side surfaces of the first and second adhesive layers 410 and 420, and the second surface 10b of the package substrate 10.

Referring to FIGS. 1A and 2C, the semiconductor package 1000 may further include a first insulating pattern 610, which is disposed on the side surface of the second semiconductor chip 200, and a second insulating pattern 620, which is disposed on the side surface of the third semiconductor chip 300. The first insulating pattern 610 and the second insulating pattern 620 may include a polymer material. The first insulating pattern 610 and the second insulating pattern 620 may include, for example, an epoxy resin. The first insulating pattern 610 and the second insulating pattern 620 may include, for example, an under-fill material. The second insulating pattern 620, which is disposed on the side surface of the third semiconductor chip 300, may be in contact with the side surface of the second adhesive layer 420, the side surface 301s of the second semiconductor substrate 301, and the side surface of the second interconnection layer 302. The second insulating pattern 620 may be disposed on the bottom surface 200b of the second semiconductor chip 200 and may not cover the second chip pad 210. For example, the second chip pad 210 may be exposed from the second insulating pattern 620. Similarly, the first insulating pattern 610 may be in contact with the side surface of the first adhesive layer 410, the side surface 201s of the first semiconductor substrate 201, and the side surface of the first interconnection layer 202. The first insulating pattern 610 may be disposed on the second surface 10b of the package substrate 10 and may not cover the second substrate pad 12. For example, the second substrate pad 12 may be exposed from the first insulating pattern 610. The conductive pattern 920 may be disposed on a side surface 610s of the first insulating pattern 610 and a side surface 620s of the second insulating pattern 620. The conductive pattern 920 may be in contact with the side surface 610s of the first insulating pattern 610 and the side surface 620s of the second insulating pattern 620. An adhesion strength between the conductive pattern 920 and the first and second insulating patterns 610 and 620 may be stronger than an adhesion strength between the conductive pattern 920 and the semiconductor substrate (e.g., 201 and 301). The first and second insulating patterns 610 and 620 may have a line shape extending in the second direction D2, when viewed in a plan view. In an embodiment, the first and second insulating patterns 610 and 620 may form a plurality of separated patterns, which are separated from each other in the second direction D2, and may be locally disposed on the side surfaces of the semiconductor chips 200 and 300 facing the conductive pattern 920. For example, the first and second insulating patterns 610 and 620 may be formed between the conductive pattern 920 and the respective second and third semiconductor chips 200 and 300. An angle 600A between the side and top surfaces of each of the first and second insulating patterns 610 and 620 may be less than 90°. For example, the angle 600A between the side surface 620s of the second insulating pattern 620 and the bottom surface 200b of the second semiconductor chip 200 may be in a range from 30° to 60°, e.g., at a point where the side surface 620s and the bottom surface 200b meet each other. Since the insulating patterns 610 and 620 having a gentle slope are disposed on the side surfaces of the second and third semiconductor chips 200 and 300, which have angles of about 90° with the second surface 10b of the package substrate 10 and the bottom surface 200b of the second semiconductor chip 200 respectively, it may be possible to prevent the conductive pattern 920 from being cut at connection regions between the second and third semiconductor chips 200 and 300 and between the second semiconductor chip 200 and the package substrate 10, due to their sharp shapes/angles. For example, the angle 600A between the side surface 620s of the second insulating pattern 620 and the bottom surface 200b of the second semiconductor chip 200 is smaller than the angle between the side surface 301s of the third semiconductor chip 300 and the bottom surface 200b of the second semiconductor chip 200.

Referring to FIGS. 1A and 3A, a bottom surface 500b of the vertical conductive pillar 500 and a bottom surface 800b of the second mold layer 820 may be coplanar with each other. The bottom surface of the vertical conductive pillar 500 may be in contact with the outer connection terminal 28. A level of the top surface of the outer connection terminal 28 may be substantially equal to or the same as a level of the bottom surface 800b of the second mold layer 820. The outer connection terminal 28 may be in contact with the bottom surface 500b of the vertical conductive pillar 500 and may not be in contact with a bottom surface 820b of the second mold layer 820. In an embodiment, the outer connection terminal 28 may be in contact with the bottom surface 820b of the second mold layer 820. In this case, a width of the top surface of the outer connection terminal 28 (i.e., in contact with the bottom surface 500b of the vertical conductive pillar 500 and the bottom surface 820b of the second mold layer 820) in the first direction D1 may be less than 120% of the width of the vertical conductive pillar 500 in the first direction D1.

Referring to FIGS. 1A and 3B, a connection pad 21 may be disposed on the bottom surface of the vertical conductive pillar 500. The connection pad 21 may be interposed between the vertical conductive pillar 500 and the outer connection terminal 28. For example, the connection pad 21 may include a seed pattern 21S and a metal pattern 21P. The seed pattern 21S may include at least one of copper, titanium, chromium, or nickel. The metal pattern 21P may include, for example, copper. The vertical conductive pillar 500 may have a first diameter 500D (e.g., in a horizontal direction—the first/second directions D1/D2), and the connection pad 21 may have a first width 21D in the first direction D1. The first width 21D may be larger than the first diameter 500D. The outer connection terminal 28 may be in contact with a bottom surface of the connection pad 21. The outer connection terminal 28 may not be in contact with the bottom surface 820b of the second mold layer 820. In an embodiment, the vertical conductive pillars 500 may have different diameters from each other.

Referring back to FIG. 1A, the vertical conductive pillars 500, which are used for signal transmission, may have a relatively small diameter, and the vertical conductive pillars 500, which are used for power supply, may have a relatively large diameter.

The connection terminals 910 may be spaced apart from each other in the first and/or second directions D1 and/or D2 by a first pitch P1. The vertical conductive pillars 500 may be spaced apart from each other in the first and/or second directions D1 and/or D2 by a second pitch P2. The first pitch P1 may be smaller than the second pitch P2. The connection terminals 910 may be respectively disposed on and contact the first chip pads 110. Therefore, the first chip pads 110 may be spaced apart from each other in the first and/or second directions D1 and/or D2 by the first pitch P1. When measured in the first direction D1, a first distance X1 between the side surface 200s of the second semiconductor chip 200, on which the conductive pattern 920 is disposed, and the vertical conductive pillar 500, which is adjacent (e.g., the closest one) thereto in the first direction D1, may be in a range from 10 μm to 130 μm. The smallest value of the first distance X1 may be 10 μm. When measured in the first direction D1, a second distance X2 between the side surface 300s of the third semiconductor chip 300, on which the conductive pattern 920 is disposed, and the side surface 200s of the second semiconductor chip 200, on which the conductive pattern 920 is disposed, may be in a range from 120 μm to 250 μm. The smallest value of the second distance X2 may be 120 μm. A third distance X3 between the bottom surface 300b of the third semiconductor chip 300 and the bottom surface 820b of the second mold layer 820 in the third direction D3 may be in a range from 5 μm to 70 μm. The smallest value of the third distance X3 may be 5 μm.

In the semiconductor package 1000 according to an embodiment of the inventive concept, the conductive pattern 920, instead of bonding wires, may be used to electrically connect the second semiconductor chip 200 to the third semiconductor chip 300 or to electrically connect the second and third semiconductor chips 200 and 300 to the package substrate 10. In a wire bonding process of connecting pads to each other, a loop-shaped structure may be formed, and thus, there may be minimum requirements for the vertical and horizontal distances in the wire bonding process/structure. For example, in the case where the bonding wires are used to electrically connect the second and third semiconductor chips 200 and 300 to the package substrate 10, 130 μm, 250 μm, and 70 μm may be required for the minimum values of the first, second, and third distances X1, X2, and X3, respectively. In the case where conductive patterns 920 are used in place of the bonding wires, the first, second, and third distances X1, X2, and X3 may be reduced by about 92%, about 52%, and about 92%, compared with a semiconductor package having the bonding wires. For example, a space required for the bonding wires may be reduced by using the conductive patterns 920 instead of the bonding wires, and thus, the height and area of the semiconductor package 1000 may be reduced. In addition, since the conductive pattern 920 is in contact with the bottom and side surfaces of the semiconductor chips 200 and 300, the conductive pattern 920 may be shorter than the bonding wire, and a length of an electric path may be reduced.

According to an embodiment of the inventive concept, the vertical conductive pillars 500 and the first semiconductor chip 100 may be separately placed on opposite surfaces of the package substrate 10. In the case where the first semiconductor chip 100 is a logic chip (e.g., AP chip) and the second and third semiconductor chips 200 and 300 are memory chips (e.g., DRAM chips), an amount of heat generated in the first semiconductor chip 100 may be greater than an amount of heat generated in the second and third semiconductor chips 200 and 300. This remains the same even when an additional memory chip is stacked on the second and third semiconductor chips 200 and 300. Due to the electric resistance of the vertical conductive pillars 500, the vertical conductive pillars 500 may function as heating sources, when the signal or voltage is transmitted or supplied through the vertical conductive pillars 500. Since the vertical conductive pillars 500 are not placed adjacent to the first semiconductor chip 100, heat may be effectively dissipated. Furthermore, in the case where the first semiconductor chip 100 is placed in a certain distance from the vertical conductive pillars 500, it may be possible to prevent or suppress signal cross-talk issues which may occur when the first semiconductor chip 100 is placed adjacent to the vertical conductive pillars 500.

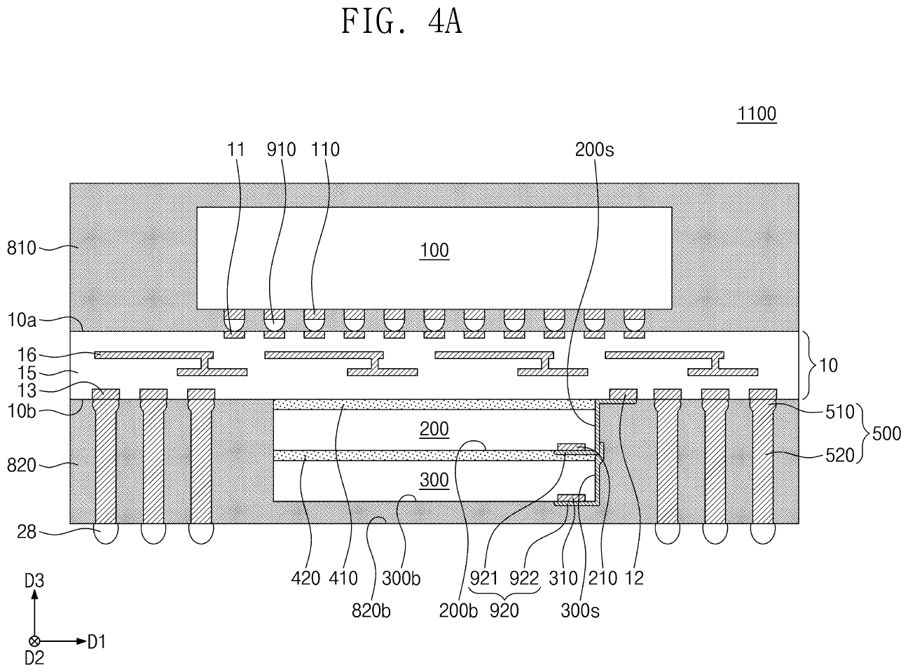

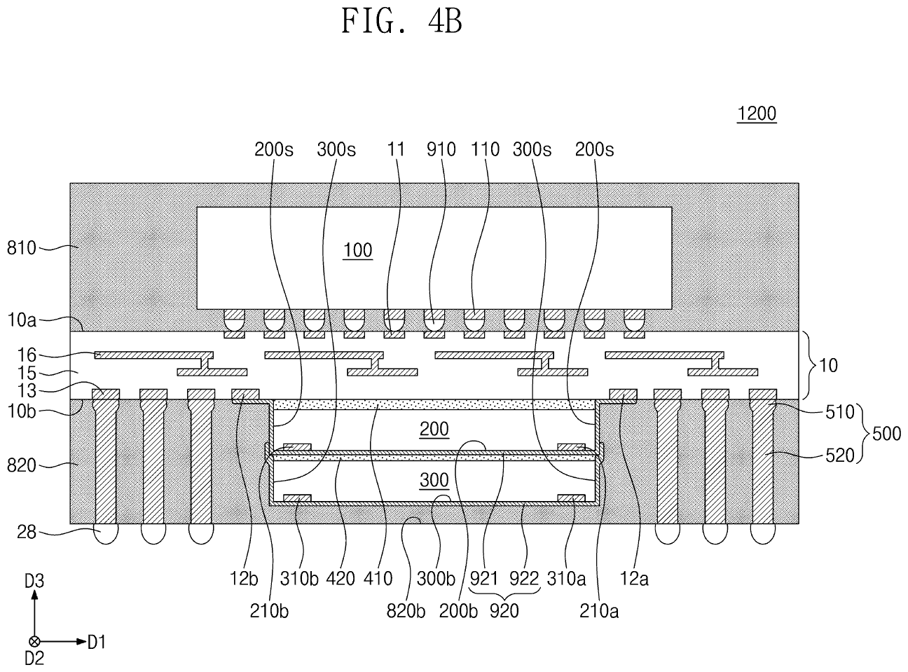

FIG. 4A is a sectional view illustrating a semiconductor package according to an embodiment of the inventive concept. Except for features to be described below, the package according to the present embodiment may have the same or substantially the same features as those described with reference to FIG. 1A, and thus, an overlapping description thereof may be omitted.

Referring to FIG. 4A, a semiconductor package 1100 may include the second and third semiconductor chips 200 and 300 whose side surfaces 200s and 300s are aligned to each other, e.g., in the vertical direction. The second chip pad 210 of the second semiconductor chip 200 may be overlapped with the third semiconductor chip 300 in the third direction D3. The conductive pattern 920 may include a first sub-conductive pattern 921 and a second sub-conductive pattern 922. The first sub-conductive pattern 921 may be connected to and be in contact with the second substrate pad 12 and the second chip pad 210. An end of the first sub-conductive pattern 921 may be placed on the bottom surface of the second substrate pad 12 or the second surface 10b of the package substrate 10 adjacent thereto, and an opposite end of the first sub-conductive pattern 921 may be placed on a bottom surface of the second chip pad 210 or the bottom surface of the second semiconductor chip 200 adjacent thereto. The first sub-conductive pattern 921 may be in contact with the bottom surface 200b and the side surface 200s of the second semiconductor chip 200 and the second surface 10b of the package substrate 10. The first adhesive layer 410 may cover or vertically overlap a portion of the first sub-conductive pattern 921 and the second chip pad 210. The second adhesive layer 420 may cover/contact a portion of a bottom surface of the first sub-conductive pattern 921 and the bottom surface of the second chip pad 210. The second sub-conductive pattern 922 may be electrically connected to and be in contact with the third chip pad 310 and the first sub-conductive pattern 921. An end of the second sub-conductive pattern 922 may be placed on a bottom surface of the third chip pad 310 or the bottom surface of the third semiconductor chip 300 adjacent thereto. An opposite end of the second sub-conductive pattern 922 may be placed on and contact a portion of the first sub-conductive pattern 921, which is disposed on the side surface 200s of the second semiconductor chip 200. For example, the second sub-conductive pattern 922 may overlap the first sub-conductive pattern 921 and the second semiconductor chip in a horizontal direction and in the vertical direction. The second sub-conductive pattern 922 may be in contact with the bottom surface 300b and the side surface 300s of the third semiconductor chip 300.

FIG. 4B is a sectional view illustrating a semiconductor package according to an embodiment of the inventive concept. Except for features to be described below, the package according to the present embodiment may have the same or substantially the same features as those described with reference to FIG. 4A, and thus, an overlapping description thereof may be omitted.

The package substrate 10 may include second substrate pads 12a and 12b, which are spaced apart from each other with the second and third semiconductor chips 200 and 300 interposed therebetween, e.g., in a plan view. The second semiconductor chip 200 may include second chip pads 210a and 210b, which are respectively placed in opposite regions thereof. For example, second chip pads 210a and 210b may be placed on opposite ends (or end portions) of the bottom surface 200b in the first direction D1. The third semiconductor chip 300 may include third chip pads 310a and 310b, which are respectively disposed in opposite regions thereof. For example, third chip pads 310a and 310b may be placed on opposite ends (or end portions) of the bottom surface 300b in the first direction D1. The second substrate pads 12a and 12b, the second chip pads 210a and 210b, and the third chip pads 310a and 310b may be arranged to be spaced apart from each other in the second direction D2, as described with reference to FIG. 1B. For example, the package substrate 10 may include a plurality of second substrate pads 12a or 12b on each side of the second semiconductor chip 200 in the first direction D1, e.g., in a plan view, the second semiconductor chip 200 may include a plurality of second chip pads 210a or 201b on each end (or end portion) of the bottom surface 200b in the first direction D1, and the third semiconductor chip 300 may include a plurality of third chip pads 310a or 310b on each end (or end portion) of the bottom surface 300b in the first direction D1. The first sub-conductive pattern 921 may be electrically connected to and be in contact with the second substrate pads 12a and 12b and the second chip pads 210a and 210b. The first sub-conductive pattern 921 may extend in the first direction D1 to cross the bottom surface 200b of the second semiconductor chip 200 and to face the opposite side surfaces 200s of the second semiconductor chip 200. For example, the first sub-conductive pattern 921 may extend in the first direction D1 on the bottom surface 200b of the second semiconductor chip 200 and on opposite side surfaces 200s of the second semiconductor chip 200 in the first direction D1 and on the second substrate pads 12a and 12b as shown in FIG. 4B.

The second sub-conductive pattern 922 may be electrically connected to and be in contact with the third chip pads 310a and 310b and portions of the first sub-conductive pattern 921, which are placed on the opposite side surfaces 200s of the second semiconductor chip 200. The second sub-conductive pattern 922 may extend in the first direction D1 to cross the bottom surface 300b of the third semiconductor chip 300 and to face the opposite side surfaces 300s of the third semiconductor chip 300. For example, the second sub-conductive pattern 922 may extend in the first direction D1 on the bottom surface 300b of the third semiconductor chip 300 and on opposite side surfaces 300s of the third semiconductor chip 300 in the first direction D1 and on the first sub-conductive pattern 921 on opposite side surfaces 200s of the second semiconductor chip 200 as shown in FIG. 4B.

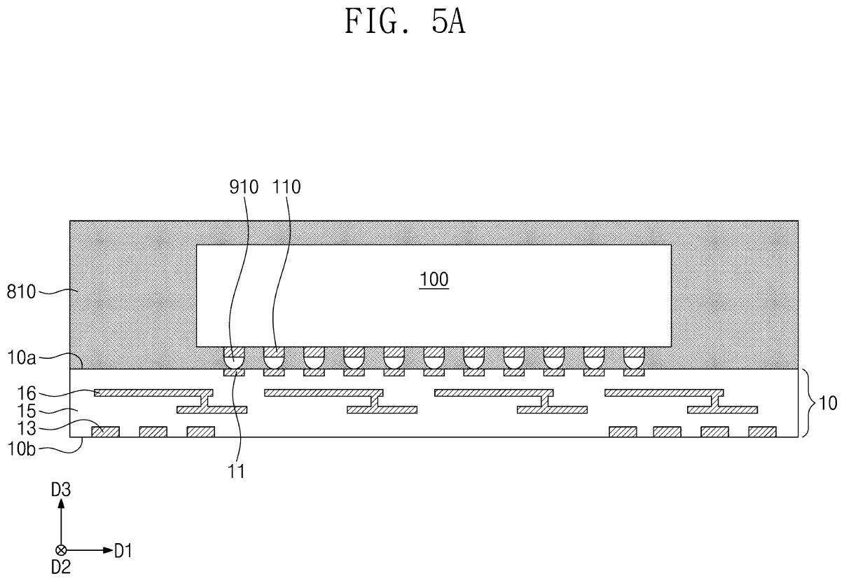

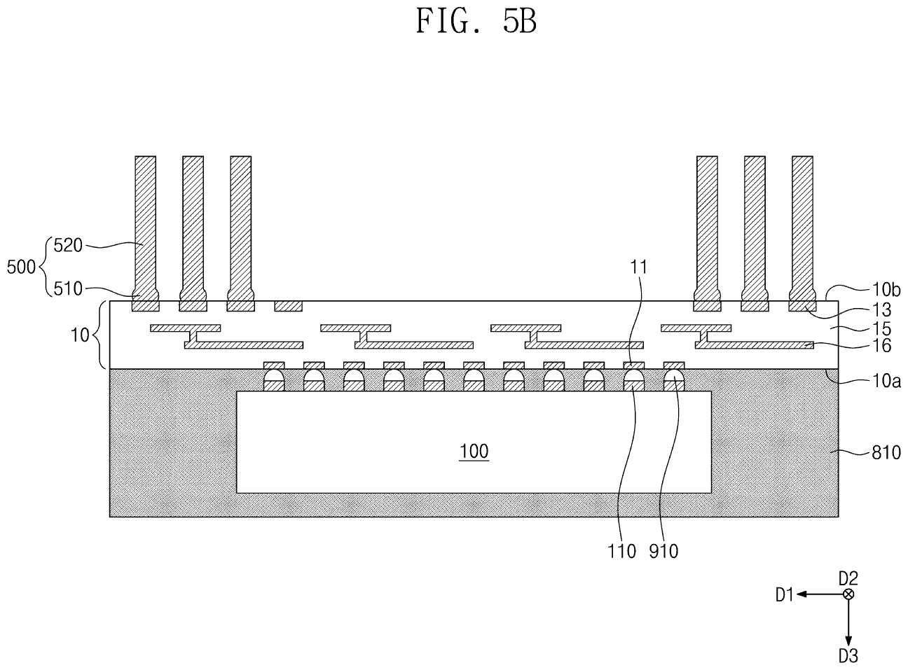

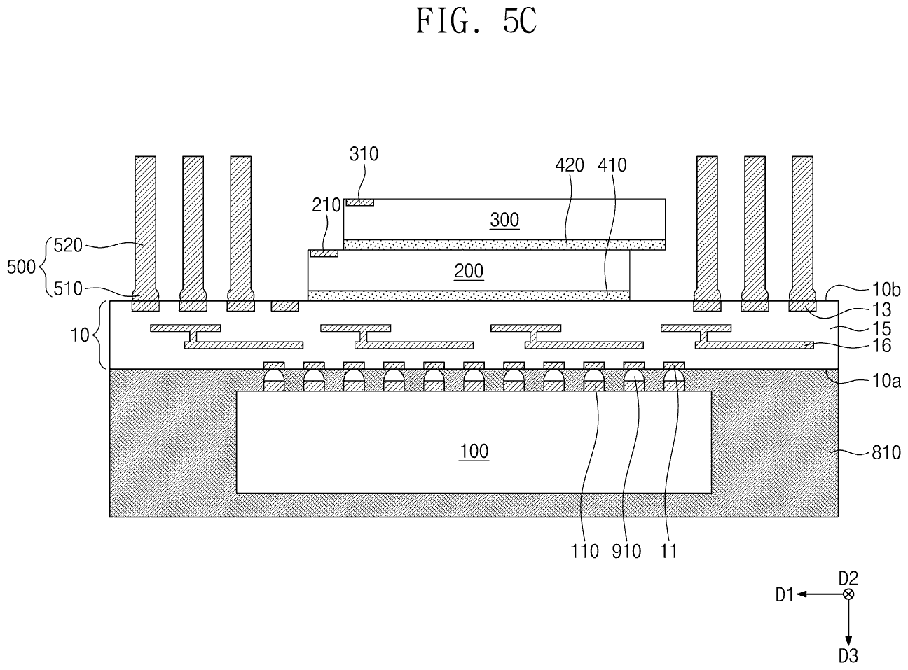

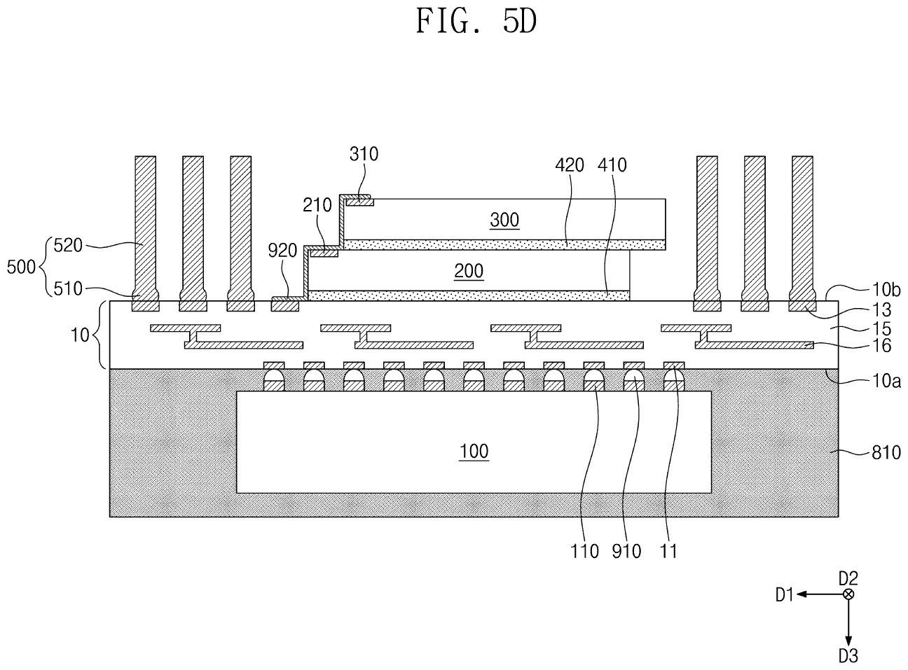

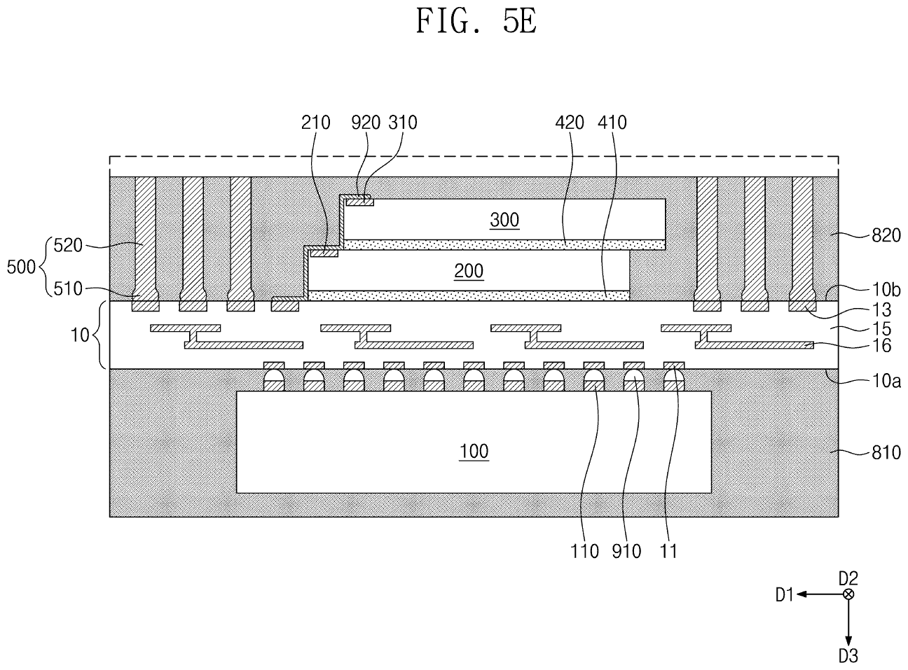

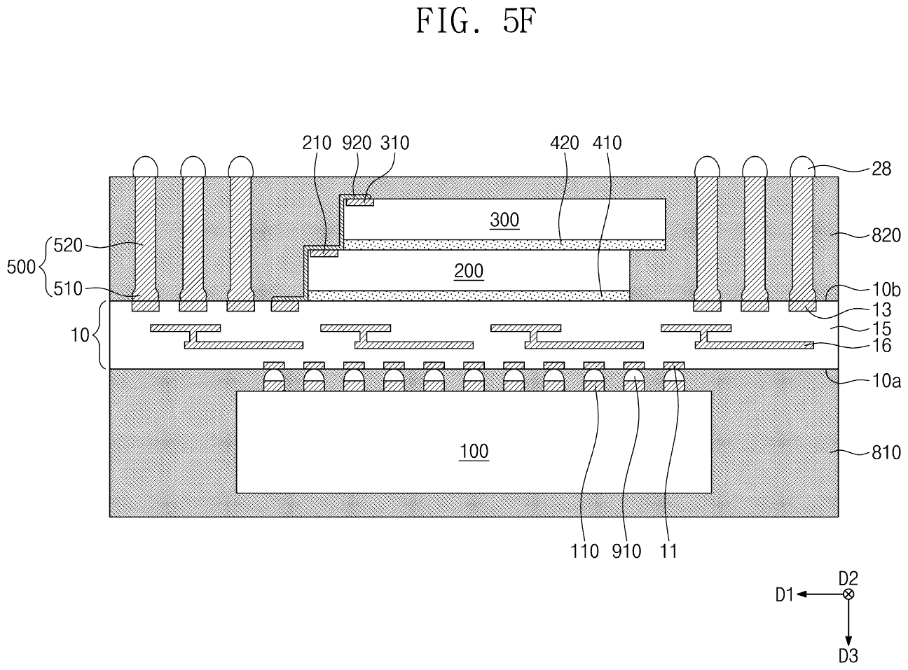

FIGS. 5A, 5B, 5C, 5D, 5E, and 5F are sectional views illustrating a process of fabricating a semiconductor package according to an embodiment of the inventive concept.

Referring to FIG. 5A, the package substrate 10 may be prepared. The first semiconductor chip 100 may be mounted on the first surface 10a of the package substrate 10. In an embodiment, the first semiconductor chip 100 may be mounted on the package substrate 10 through a flip-chip bonding method. The first mold layer 810 may be formed on the first surface 10a of the package substrate 10, the top and side surfaces of the first semiconductor chip 100, and to fill a space between the connection terminals 910.

Referring to FIG. 5B, the package substrate 10 may be vertically inverted in such a way that the second surface 10b of the package substrate 10 is placed at an upper level than the first surface 10a. The vertical conductive pillars 500 may be formed on the exposed top surfaces of the third substrate pads 13 as shown in FIG. 5B. In an embodiment, the formation of the vertical conductive pillars 500 may include a wire bonding process or a metal pin bonding process. The wire bonding process may include attaching metal wires to the third substrate pads 13. The metal pin bonding process may include attaching metal pins to the third substrate pads 13. The metal wires or the metal pins may be attached to the third substrate pad 13 by an ultrasonic wave, heat, or pressure to form the first portion 510 of the vertical conductive pillar 500. The remaining portion excluding the attached portion may have a line shape or a cylindrical shape extending (e.g., lengthwise) in the third direction D3. For example, the first portion 510 of the vertical conductive pillar 500 may be formed during the attaching/bonding process of the vertical conductive pillar 500 onto the third substrate pads 13 to have a wider width than the second portion 520 by the pressure, the heat, and/or the ultrasonic wave used for the attachment or bonding.

Referring to FIG. 5C, the second semiconductor chip 200 may be attached to the second surface 10b of the package substrate 10. The first adhesive layer 410 may be disposed on a surface of the second semiconductor chip 200, which is opposite to the active surface of the second semiconductor chip 200 provided with the second chip pad 210. For example, the surface of the second semiconductor chip 200 on which the first adhesive layer 410 is disposed may be an inactive surface of the second semiconductor chip 200. The second semiconductor chip 200 may be attached to the package substrate 10 using the first adhesive layer 410. Next, the second adhesive layer 420 may be attached/disposed to a surface of the third semiconductor chip 300, which is opposite to the active surface of the third semiconductor chip 300 provided with the third chip pad 310. For example, the surface of the third semiconductor chip 300 on which the second adhesive layer 420 is disposed may be an inactive surface of the third semiconductor chip 300. The third semiconductor chip 300 may be attached to the second semiconductor chip 200 using the second adhesive layer 420. The second adhesive layer 420 and the third semiconductor chip 300 may be attached to the second semiconductor chip 200 in an offset manner to expose the second chip pad 210.

Referring to FIG. 5D, the conductive pattern 920 may be formed to electrically connect the second substrate pad 12, the second chip pad 210, and the third chip pad 310 to each other. The conductive pattern 920 may be formed by selectively depositing, coating, or printing a metallic material on a desired region. The conductive pattern 920 may be formed by forming a metallic material layer/pattern using a laser direct structuring, dispensing, and/or inkjet printing method. In an embodiment, before the formation of the conductive pattern 920, the first insulating pattern 610 may be formed on the side surface of the second semiconductor chip 200, and the second insulating pattern 620 may be formed on the side surface of the third semiconductor chip 300. The formation of the first and second insulating patterns 610 and 620 may include forming a polymer insulating material layer (e.g., with an under-fill material or another) on the side surface 200s of the second semiconductor chip 200 and the side surface 300s of the third semiconductor chip 300 (e.g., using a coating method). The formation of the first and second insulating patterns 610 and 620 may further include patterning the polymer insulating material layer to form the first and second insulating patterns 610 and 620.

Referring to FIG. 5E, the second mold layer 820 may be formed to cover the second surface 10b of the package substrate 10, the top and side surfaces of the second semiconductor chip 200, the top and side surfaces of the third semiconductor chip 300, and the top and side surfaces of the vertical conductive pillars 500. Next, a planarization process may be performed to remove a portion of the second mold layer 820 and to expose the top surfaces of the vertical conductive pillars 500. During the planarization process, each of the vertical conductive pillars 500 may be partially removed. As a result of the planarization process, the top surfaces of the vertical conductive pillars 500 may be exposed from a top surface of the second mold layer 820, and the heights of the vertical conductive pillars 500 in the third direction D3 may be controlled in substantially the same manner. For example, the planarization process may remove top portions of the vertical conductive pillars 500 such that the vertical conductive pillars 500 have the same height in the third direction D3. The top surfaces of the vertical conductive pillars 500 may be coplanar with the top surface of the second mold layer 820.

Referring to FIG. 5F, the outer connection terminals 28 may be formed on the exposed top surfaces of the vertical conductive pillars 500, respectively. In an embodiment, the outer connection terminals 28 may be formed by performing at least one of a solder ball attaching process, a solder paste process, a solder plating process, and a solder ball laser direct structuring process. The outer connection terminal 28 may have a stronger adhesion strength to the vertical conductive pillar 500 than to the second mold layer 820. The size of the outer connection terminal 28 may be adjusted to prevent delamination of the outer connection terminal 28 and to prevent the outer connection terminal 28 from being in contact with the second mold layer 820. For example, the outer connection terminal 28 may be formed to have a diameter similar to the vertical conductive pillar 500. For example, the outer connection terminal 28 may have the same diameter as the vertical conductive pillar 500 on a plane at which a boundary between the outer connection terminal 28 and the vertical conductive pillar 500. Diameters of the outer connection terminal 28 and the vertical conductive pillar 500 may be measured in the first direction D1 or the second direction D2. Next, the second mold layer 820, the package substrate 10, and the first mold layer 810 may be sawed to form the semiconductor package 1000 shown in FIG. 1A.

In an embodiment, as shown in FIG. 3B, the connection pad 21 may be formed between the outer connection terminal 28 and the vertical conductive pillar 500. The formation of the connection pad 21 may be performed before the formation of the outer connection terminal 28. The formation of the connection pad 21 may include forming a seed layer on the vertical conductive pillar 500 and the second mold layer 820, forming a photoresist pattern, which includes an opening overlapped with (e.g., exposing) the vertical conductive pillar 500 in the third direction D3, forming the metal pattern CP using the seed layer as an electrode, forming a solder layer on the metal pattern CP using a plating process, removing the photoresist pattern, etching the seed layer to form the seed pattern SP, and reflowing the solder layer to form the outer connection terminal 28. Here, the opening of the photoresist pattern may be adjusted to be larger than the diameter 500D of the vertical conductive pillar 500. The outer connection terminal 28 may have the same diameter as the connection pad 21 on a plane at which a boundary between the outer connection terminal 28 and the connection pad 21. Diameters of the outer connection terminal 28 and the connection pad 21 may be measured in the first direction D1 or the second direction D2.

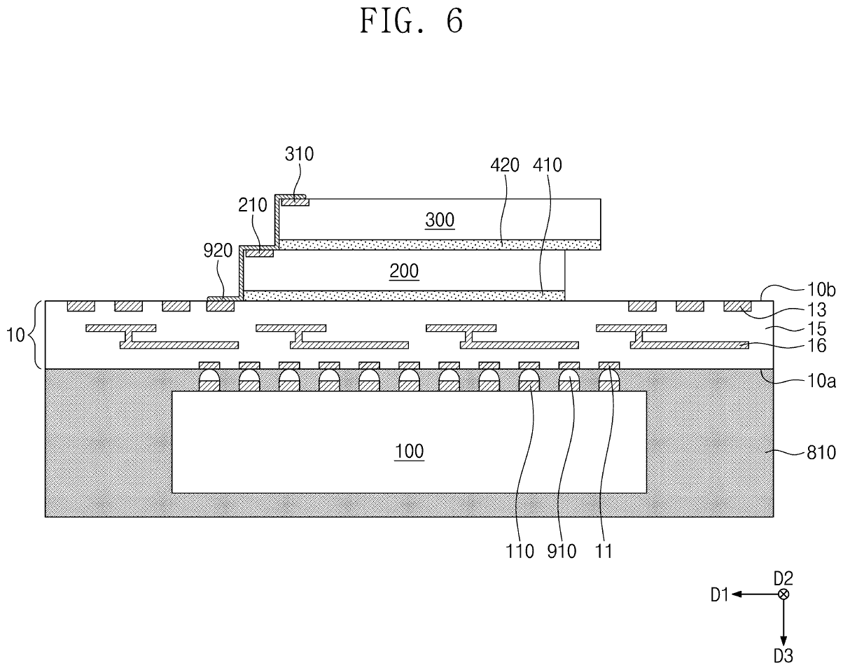

FIG. 6 is a sectional view illustrating a process of fabricating a semiconductor package according to an embodiment of the inventive concept.

Referring to FIGS. 5A and 6, the package substrate 10 may be vertically inverted in such a way that the second surface 10b of the package substrate 10 is placed at an upper level than the first surface 10a after the process illustrated in FIG. 5A. The second and third semiconductor chips 200 and 300 may be stacked in an offset manner on the second surface 10b of the package substrate 10, before the formation of the vertical conductive pillars 500. In an embodiment, the second and third semiconductor chips 200 and 300 may be stacked in the same manner as described above with respect to FIG. 5C. The conductive pattern 920 may be formed to electrically connect the second substrate pad 12, the second chip pad 210, and the third chip pad 310 to each other. The formation of the conductive pattern 920 may include depositing and plating a metallic material to form a metal layer on the second surface 10b of the package substrate 10, the top and side surfaces of the second semiconductor chip 200, and the top and side surfaces of the third semiconductor chip 300, and patterning the metal layer to leave the metallic material pattern on a desired region. In an embodiment, the conductive pattern 920 may be formed by a metal sputtering process, an electroplating process, and an electroless plating process. In the case where the conductive pattern 920 is formed through an electroplating process using a seed layer, the conductive pattern 920 may include the seed pattern SP, as shown in FIG. 2B. After forming the conductive pattern 920, vertical conductive pillars 500 may be formed on the third substrate pads 13 in the same way as described with respect to FIG. 5B. After forming the vertical conductive pillars 500, following processes described with respect to FIGS. 5E and 5F may be performed to complete the semiconductor package.

In a semiconductor package according to an embodiment of the inventive concept, stacked semiconductor chips may be electrically connected to each other through a connection terminal that is in contact with an active surface and a side surface thereof. In this case, the thickness and area (e.g., a plan view area) of the semiconductor package may be reduced. Furthermore, the semiconductor package may have a single package structure sharing a single substrate with multiple semiconductor chips and additional elements. For example, a logic chip and a vertical conductive pillar may be placed on different surfaces of the substrate. In this case, heat generated from the semiconductor package may be effectively dissipated and cross-talk issues in the semiconductor package may be reduced. Accordingly, the reliability of the semiconductor package may be improved.

Even though different figures illustrate variations of exemplary embodiments and different embodiments disclose different features from each other, these figures and embodiments are not necessarily intended to be mutually exclusive from each other. Rather, features depicted in different figures and/or described above in different embodiments can be combined with other features from other figures/embodiments to result in additional variations of embodiments, when taking the figures and related descriptions of embodiments as a whole into consideration. For example, components and/or features of different embodiments described above can be combined with components and/or features of other embodiments interchangeably or additionally to form additional embodiments unless the context clearly indicates otherwise, and the present disclosure includes the additional embodiments.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a package substrate including a first surface and a second surface, which are opposite to each other;
a first semiconductor chip on the first surface;
a first mold layer on the first surface of the package substrate and a top surface and a side surface of the first semiconductor chip;
a second semiconductor chip and a third semiconductor chip stacked on the second surface;
a second mold layer on the second surface of the package substrate, bottom and side surfaces of the second semiconductor chip, and bottom and side surfaces of the third semiconductor chip;
a vertical conductive pillar, which is provided to penetrate the second mold layer in a vertical direction and is horizontally spaced apart from the second and third semiconductor chips; and
connection terminals between a bottom surface of the first semiconductor chip and the first surface,
wherein the vertical conductive pillar is placed on the second surface.

2. The semiconductor package of claim 1, wherein the first semiconductor chip is a logic chip, and
the second and third semiconductor chips are memory chips.

3. The semiconductor package of claim 1, wherein the vertical conductive pillar comprises at least one of a metal wire or a metal pin.

4. The semiconductor package of claim 1, further comprising an outer connection terminal on the vertical conductive pillar,
wherein the outer connection terminal is in contact with the vertical conductive pillar.

5. The semiconductor package of claim 4, wherein the semiconductor package comprises a plurality of vertical conductive pillars on the second surface and a plurality of outer connection terminals on the plurality of vertical conductive pillars, and
the outer connection terminals are spaced apart from the second and third semiconductor chips and are provided to enclose the second and third semiconductor chips, when viewed in a plan view.

6. The semiconductor package of claim 4, wherein a level of a top surface of the outer connection terminal is substantially equal to a level of a bottom surface of the second mold layer.

7. The semiconductor package of claim 1, further comprising:
a connection pad on the vertical conductive pillar; and
an outer connection terminal spaced apart from the vertical conductive pillar, with the connection pad interposed therebetween,
wherein the vertical conductive pillar has a first diameter in a first direction parallel to the first surface,
the connection pad has a first width in the first direction, and
the first width is larger than the first diameter.

8. The semiconductor package of claim 1, wherein a height of the vertical conductive pillar is larger than a sum of thicknesses of the second and third semiconductor chips.

9. A semiconductor package, comprising:
a package substrate including a first surface and a second surface, which are opposite to each other, the package substrate comprising a first substrate pad on the first surface and a second substrate pad on the second surface;
a first semiconductor chip on the first surface, the first semiconductor chip comprising a first chip pad;
a connection terminal between the first substrate pad and the first chip pad;
a second semiconductor chip on the second surface, the second semiconductor chip comprising a second chip pad on a bottom surface thereof;
a third semiconductor chip spaced apart from the package substrate with the second semiconductor chip interposed therebetween, the third semiconductor chip comprising a third chip pad on a bottom surface thereof; and
a conductive pattern electrically connecting the second substrate pad, the second chip pad, and the third chip pad to each other,
wherein the conductive pattern is in contact with the bottom surface of the second semiconductor chip and the bottom surface of the third semiconductor chip.

10. The semiconductor package of claim 9, wherein the conductive pattern is in contact with a side surface of the second semiconductor chip and a side surface of the third semiconductor chip.

11. The semiconductor package of claim 9, wherein the conductive pattern comprises a seed pattern,
the seed pattern comprises at least one of copper, titanium, chromium, or nickel,
the seed pattern is in contact with the bottom surface of the second semiconductor chip and the bottom surface of the third semiconductor chip.

12. The semiconductor package of claim 9, wherein the third semiconductor chip is stacked on the second semiconductor chip to be offset from the second semiconductor chip in a first direction,
the package substrate comprises a plurality of second substrate pads,
the second semiconductor chip comprises a plurality of second chip pads,
the third semiconductor chip comprises a plurality of third chip pads,
the semiconductor package comprises a plurality of conductive patterns,
the second substrate pads are spaced apart from each other in a second direction perpendicular to the first direction,
the second chip pads are spaced apart from each other in the second direction,
the third chip pads are spaced apart from each other in the second direction, and
the conductive patterns are spaced apart from each other in the second direction.

13. The semiconductor package of claim 9, further comprising a mold layer on the second surface,
wherein the mold layer covers the second and third semiconductor chips, and
the mold layer is not interposed between the conductive pattern and the second semiconductor chip and between the conductive pattern and the third semiconductor chip.

14. The semiconductor package of claim 9, wherein the conductive pattern has a stepwise pattern that continuously extends from a bottom surface of the second substrate pad to a bottom surface of the second chip pad and to a bottom surface of the third chip pad.

15. A semiconductor package, comprising:
a package substrate including a first surface and a second surface, which are opposite to each other, the package substrate comprising a first substrate pad on the first surface and a second substrate pad and a third substrate pad on the second surface;
a first semiconductor chip on the first surface, the first semiconductor chip comprising a first chip pad;
a connection terminal between the first substrate pad and the first chip pad;
a first mold layer on the first surface of the package substrate and top and side surfaces of the first semiconductor chip;
a second semiconductor chip on the second surface of the package substrate, the second semiconductor chip comprising a second chip pad;
a third semiconductor chip spaced apart from the package substrate with the second semiconductor chip interposed therebetween, the third semiconductor chip comprising a third chip pad;
a first adhesive layer between the second surface and the second semiconductor chip;
a second adhesive layer between the second semiconductor chip and the third semiconductor chip;
a second mold layer on the second surface, a bottom surface of the second semiconductor chip, and bottom and side surfaces of the third semiconductor chip;
a conductive pattern electrically connecting the second chip pad, the third chip pad, and the second substrate pad to each other;
a vertical conductive pillar provided on the third substrate pad to penetrate the second mold layer in a vertical direction; and
an outer connection terminal on the vertical conductive pillar,
wherein the conductive pattern has a line shape extending in a direction parallel to the first surface, on the bottom surface of the second semiconductor chip.

16. The semiconductor package of claim 15, further comprising an insulating pattern on a side surface of the third semiconductor chip,
wherein the conductive pattern is in contact with the insulating pattern, and
the insulating pattern comprises a polymer material.

17. The semiconductor package of claim 16, wherein a first angle between a side surface of the insulating pattern and the bottom surface of the second semiconductor chip is smaller than a second angle between the side surface of the third semiconductor chip and the bottom surface of the second semiconductor chip.

18. The semiconductor package of claim 15, wherein the first semiconductor chip comprise a plurality of first chip pads,
the semiconductor package comprises a plurality of vertical conductive pillars is provided on a plurality of third substrate pads,
the first chip pads are arranged at a first pitch,
the vertical conductive pillars are arranged at a second pitch, and
the first pitch is smaller than the second pitch.

19. The semiconductor package of claim 15, wherein the second and third semiconductor chips have side surfaces that are aligned to each other in the vertical direction,
the conductive pattern comprises:
a first sub-conductive pattern in contact with the second substrate pad, the side surface of the second semiconductor chip, and the second chip pad; and
a second sub-conductive pattern in contact with the first sub-conductive pattern, the side surface of the third semiconductor chip, and the third chip pad.

20. The semiconductor package of claim 15, wherein the third semiconductor chip is stacked on the second semiconductor chip and is offset from the second semiconductor chip in a first direction,
a first distance, in the first direction, between a first side surface of the second semiconductor chip, on which the conductive pattern is disposed, and the vertical conductive pillar is in a range from 10 μm to 130 μm,
a second distance between a second side surface of the third semiconductor chip, on which the conductive pattern is disposed, and the first side surface of the second semiconductor chip in the first direction is in a range from 120 μm to 250 μm, and
a third distance between a bottom surface of the third semiconductor chip and a bottom surface of the second mold layer is in a range from 5 μm to 70 μm.
